(19) United States
(12) Patent Application Publication
(10) Pub. No.: US 2015/0356926 A1
(43) Pub. Date: Dec. 10, 2015

(54) STRETCHABLE DISPLAY AND FABRICATING METHOD THEREOF

(71) Applicant: SAMSUNG DISPLAY CO., LTD., Yongin-City (KR)

(72) Inventor: Jong-Sung BAE, Yongin-City (KR)

(21) Appl. No.: 14/594,556

(22) Filed: Jan. 12, 2015

(30) Foreign Application Priority Data
Jun. 9, 2014 (KR) 10-2014-0069510

(51) Int. Cl. G09G 3/32; H01L 51/56; H01L 51/00; H01L 27/32; H01L 51/52

(52) U.S. Cl. CPC G09G 3/3291; H01L 27/3276; H01L 27/3288; H01L 51/5253; H01L 51/5271; H01L 51/0005; H01L 51/56; G09G 3/3208; H01L 2251/5338; H01L 51/5012

(57) ABSTRACT

A stretchable display includes a substrate, first wires on the substrate, second wire on the first wires, the second wires intersecting the first wires, organic light emitting layers at intersections of the first and second wires, and encapsulation layers formed on the respective organic light emitting layers. The encapsulation layers individually cover the respective organic light emitting layers.

### CROSS-REFERENCE TO RELATED APPLICATION

Korean Patent Application No. 10-2014-0069510, filed on Jun. 9, 2014, in the Korean Intellectual Property Office, and entitled: “Stretchable Display and Fabricating Method Thereof,” is incorporated by reference herein in its entirety.

### BACKGROUND

1. Field

Embodiments relate to a stretchable display and a method of fabricating the stretchable display.

2. Description of the Related Art

With the development of an information-oriented society, a display device for displaying an image has increased requirements. Recently, various types of flat panel display devices have been developed, such as liquid crystal displays, plasma display devices, organic light emitting displays, and electrophoretic displays. In recent years, research has been continuously conducted to implement the flat panel display devices, such as the organic light emitting displays or the electrophoretic displays, in the form of flexible displays having flexibility.

The flexible displays may be classified into a curved display that is formed such that the flat panel display has a curved shape, a foldable display that is formed such that flat panel display is foldable, and a stretchable display that is formed such that the flat panel display is bendable or stretchable. The curved display and the foldable display have become available commercially, and thus are being produced by many manufacturing companies.

### SUMMARY

Embodiments are directed to a stretchable display including a substrate, first wires on the substrate, second wires on the first wires, the second wires intersecting the first wires, organic light emitting layers at intersections of the first and second wires, and encapsulation layers on the respective organic light emitting layers, the encapsulation layers individually covering the respective organic light emitting layers.

The stretchable display may further include an insulation layer between the first wires and the second wires, the insulation layer electrically insulating the first wires from the second wires.

The organic light emitting layers may directly contact the second wires and may contact the first wires via a contact hole, the contact hole extending through the insulation layer to expose the first wires.

Each of the first wires may include a first electric conductive wire and a first insulator wrapped around the first electric conductive wire.

The organic light emitting layers may contact the first electric conductive wire via a first contact hole, the first contact hole extending through the first insulator to expose the first electric conductive wire.

Each of the second wires may include a second electric conductive wire and a second insulator wrapped around the second electric conductive wire.

The organic light emitting layers may contact the second electric conductive wire via a second contact hole, the second contact hole extending through the second insulator to expose the second electric conductive wire.

The stretchable display may further include a first driver that supplies a first drive voltage to the first wires and a second driver that supplies second drive voltages to the second wires.

The stretchable display may further include an integrated driver that simultaneously supplies the first drive voltage to the first wires and supplies the second drive voltages to the second wires.

The substrate may have a rectangular shape, a circular shape, or a fan shape.

The substrate may include a reflecting plate.

Embodiments are also directed to a method of fabricating a stretchable display including securing a stretchable substrate to a support substrate, forming first wires on the stretchable substrate, forming second wires to intersect with the first wires, forming organic light emitting layers by dropping an organic light emitting material onto intersections of the first and second wires, and forming encapsulation layers by dropping an encapsulation material onto the respective organic light emitting layers to individually cover the respective organic light emitting layers.

The method may further include forming an insulation layer between the first wires and the second wires to electrically insulate the first wires from the second wires.

The method may further include forming at least one contact hole through the insulation layer to expose the first wires.

Forming the organic light emitting layers by dropping the organic light emitting material onto the intersections of the first and second wires may include dropping the organic light emitting material to cover the intersections of the first and second wires and the contact hole.

The method may further include forming a first contact hole through an insulation material of the first wires to expose an electric conductive material of the first wires, and forming a second contact hole through an insulation material of the second wires to expose an electric conductive material of the second wires.

Forming the organic light emitting layers by dropping the organic light emitting material onto the intersections of the first and second wires may include dropping the organic light emitting material to cover the intersections of the first and second wires and the first and second contact holes using an inkjet device.

Forming the encapsulation layers by dropping the encapsulation material to the respective organic light emitting layers to cover the respective organic light emitting layers may include dropping the encapsulation material onto the respective organic light emitting layers using an inkjet device.

Embodiments are also directed to a method of fabricating a stretchable display including securing a stretchable substrate to a support substrate, forming first contact holes by etching first insulators of first wires formed on the stretchable substrate, the first contact holes exposing first electric conductive wires of the first wires, forming second contact holes by etching second insulators of second wires formed on the stretchable substrate, the second contact holes exposing second electric conductive wires of the second wires, forming organic light emitting layers by dropping an organic light emitting material to cover intersections of the first and second wires and the first and second contact holes, and forming encapsulation layers by dropping an encapsulation material onto the respective organic light emitting layers to individually cover the respective organic light emitting layers.

Forming the organic light emitting layers by dropping the organic light emitting material to cover the intersections of the first and second wires and the first and second contact holes may be carried out using an inkjet device. Forming the encapsulation layers by dropping the encapsulation material onto the respective organic light emitting layers to cover the respective organic light emitting layers may be carried out using the inkjet device.

### BRIEF DESCRIPTION OF THE DRAWINGS

Features will become apparent to those of skill in the art by describing in detail exemplary embodiments with reference to the attached drawings in which:

FIG. 1 illustrates a view of a display panel of a stretchable display according to an embodiment;

FIG. 2 illustrates a detailed plan view of portion of the display panel in FIG. 1;

FIG. 3 illustrates a sectional view taken along line I-I′ of FIG. 2;

FIG. 4 illustrates a flowchart of a method of fabricating the stretchable display according to the embodiment;

FIGS. 5A to 5F illustrate views of stages of a method of fabricating the stretchable display according to the embodiment;

FIG. 6 illustrates a view of a display panel of a stretchable display according to a another embodiment;

FIG. 7 illustrates a detailed plan view of portion of the display panel in FIG. 6;

FIG. 8 illustrates a sectional view taken along line II-II′ of FIG. 7;

FIG. 9 illustrates a flowchart depicting a method of fabricating the stretchable display according to the embodiment illustrated in FIG. 6;

FIGS. 10A to 10D illustrate views illustrating stages of a method of fabricating the stretchable display according to the embodiment illustrated in FIG. 6;

FIG. 11 illustrates a block diagram of a stretchable display according to an embodiment;

FIG. 12 illustrates a block diagram of a stretchable display according to another embodiment;

FIG. 13 illustrates a block diagram of a stretchable display according to a further embodiment;

FIG. 14 illustrates a block diagram of a stretchable display according to another embodiment;

FIG. 15 illustrates a block diagram of a stretchable display according to another embodiment;

FIG. 16 illustrates a block diagram of a stretchable display according to another embodiment; and

FIG. 17 illustrates a view depicting an application example for the stretchable display according to embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

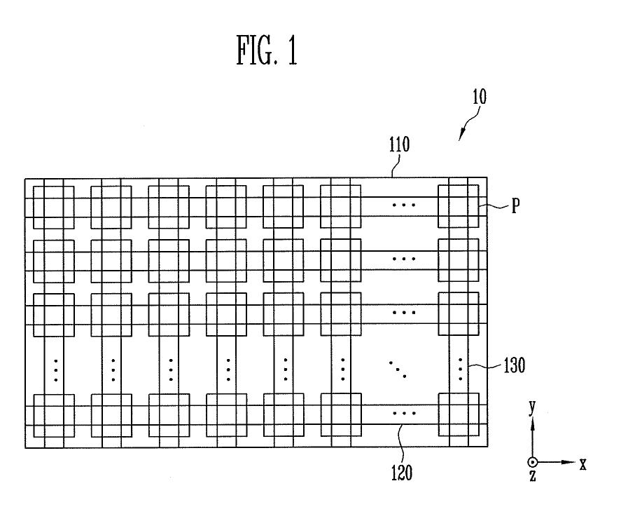

FIG. 1 illustrates a view depicting a display panel of a stretchable display according to an embodiment. Referring to FIG. 1, the display panel 10 of the stretchable display according to this embodiment includes a substrate 110, first wires 120, second wires 130 and pixels P.

The substrate 110 may be a stretchable substrate. The substrate 110 may be made of bendable and stretchable plastics as well as fabric. The substrate 110 may be made of a bendable and stretchable materials, such as, for example bendable and stretchable plastics or fabric.

The substrate 110 may include a reflecting plate. The reflecting plate may be formed on the substrate 110. The reflecting plate may be bendable and stretchable. For example, the reflecting plate may be a flexible foil.

The first wires 120 and the second wires 130 may be formed on the substrate 110 or on the reflecting plate of the substrate 110. The first wires 120 and the second wires 130 may be formed to intersect each other. For example, the first wires 120 may be formed to be parallel to each other in a horizontal direction (x-axis direction), and the second wires 120 may be formed to be parallel to each other in a vertical direction (y-axis direction).

The first wires 120 and the second wires 130 may be formed on different layers. In order to insulate the first and second wires 120 and 130 from each other, an insulation layer may be formed between the first and second wires 120 and 130. The first and second wires 120 and 130 may be formed of stretchable nano wires.

The pixels P may be formed on intersections of the first and second wires 120 and 130. Each of the pixels P may include n intersections (where n is a positive integer). For example, as shown in FIG. 1, each of the pixels P may include four intersections. The pixels P may include red pixels, green pixels or blue pixels, respectively.

Each pixel P may include an organic light emitting layer and an encapsulation layer. The organic light emitting layer is a layer that contains an organic light emitting material to emit light when a current flows. The organic light emitting layer may be a red organic light emitting layer for emitting red light, a green organic light emitting layer for emitting green light, or a blue organic light emitting layer for emitting blue light. The encapsulation layer may be a layer that covers the organic light emitting layer to protect the organic light emitting layer.

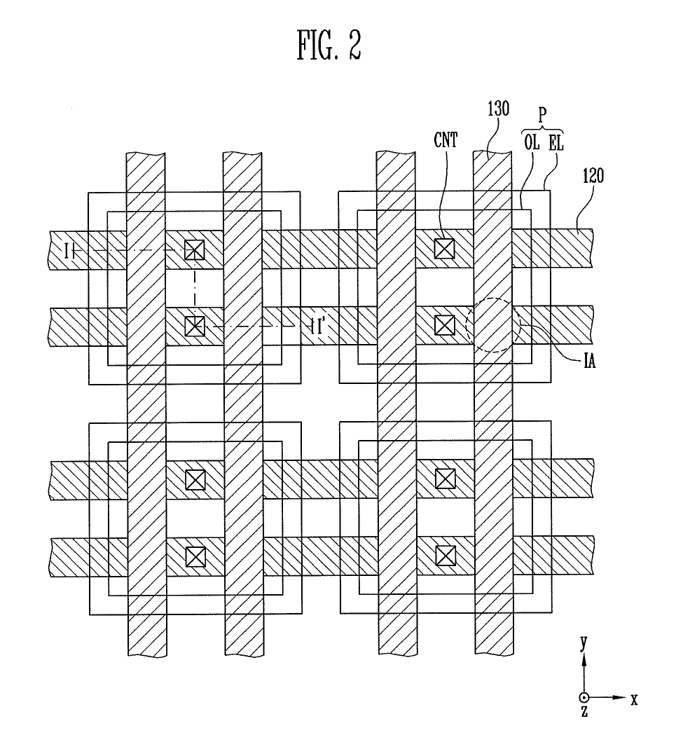

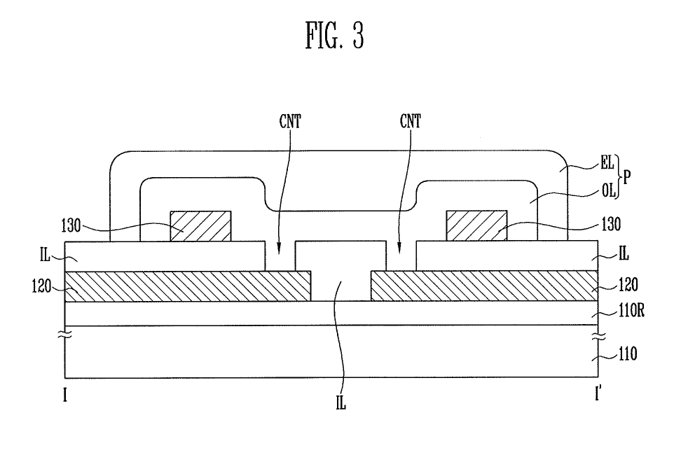

Hereinafter, each pixel P will be described in detail with reference to FIGS. 2 and 3.

FIG. 2 illustrates a detailed plan view depicting a portion of the display panel in FIG. 1. FIG. 3 illustrates a sectional view taken along line I-I′ of FIG. 2. In FIGS. 2 and 3, the pixel P includes the organic light emitting layer OL and the encapsulation layer EL. The pixel P is formed to cover the four intersections IA.

Referring to FIGS. 2 and 3, the first wires 120 may be formed on the substrate 110 or on the reflecting plate 100R of the substrate 110. The first wires 120 may be formed in the horizontal direction (x-axis direction). The first wires 120 may be formed of nano wires of a stretchable material, for example, copper (Cu), silver (Ag), gold (Au), graphene, carbon nano tube (CNT), copper phthalocyanine (CuPc), etc.

The insulation layer IL may be formed on the first wires 120. The insulation layer IL may be formed of silicon nitride (SiNx), a double layer of silicon nitride (SiNx)/silicon dioxide (SiO₂) or polyimide, as examples.

By etching the insulation layer IL, a contact hole CNT may be formed through the insulation layer IL to expose the first wires 120. As shown in FIG. 2, the contact hole CNT may be formed between the intersections IA to expose the first wires 120.

The second wires 130 may be formed on the insulation layer IL. The first wires 120 and the second wires 130 may be electrically insulated from each other by the insulation layer IL. The second wires 130 may be formed in the vertical direction (y-axis direction). Thus, the first wires 120 and the second wires 130 may be formed on different layers in such a way as to intersect with each other. The second wires 130 may be formed of nano wires of a stretchable material, for example, copper (Cu), silver (Ag), gold (Au), graphene, carbon nano tube (CNT), copper phthalocyanine (CuPc), etc.

The organic light emitting layer OL may be formed on the second wires 130. The organic light emitting layer OL may be formed to cover n intersections IA of the first wires 120 with the second wires 130. For example, the organic light emitting layer OL may be formed to cover four intersections IA. The organic light emitting layer OL may be in contact with the first wires 120 via the contact hole CNT, and may be in direct contact with the second wires 120.

When a first voltage is supplied to the first wire 120 and a second voltage higher than the first voltage is supplied to the second wire 130, a current may flow from the second wire 130 through the organic light emitting layer OL to the first wire 120, such that the organic light emitting layer OL may emit light. When the second voltage is supplied to the first wire 120 and the first voltage is supplied to the second wire 130, a current may flow from the first wire 120 through the organic light emitting layer OL to the second wire 130, such that the organic light emitting layer OL may emit light.

The encapsulation layer EL may be formed on the organic light emitting layer OL. The encapsulation layer EL may be formed to cover the organic light emitting layer OL, thus encapsulating the organic light emitting layer OL. The encapsulation layer EL is not formed throughout a whole surface of the substrate 110. As shown in FIGS. 2 and 3, the encapsulation layer EL may be formed to be wider than each organic light emitting layer OL, thus covering each organic light emitting layer OL. According to this embodiment, the organic light emitting layer OL is individually encapsulated with respect to every pixel, using the encapsulation layer EL.

According to comparative embodiments, the encapsulation layer EL is formed throughout the whole surface of the substrate 110. In this case, if the substrate 110 is excessively stretched, the organic light emitting layer OL or the encapsulation layer EL of the pixel P may be damaged because the organic light emitting layer OL or the encapsulation layer EL of the pixel P must also be stretched. However, when the organic light emitting layer OL is individually encapsulated, with respect to every pixel, using the encapsulation layer EL according to this embodiment, even though the substrate 110 is excessively stretched, the organic light emitting layer OL or the encapsulation layer EL of the pixel P may not be damaged because the organic light emitting layer OL or the encapsulation layer EL of the pixel P is not stretched when the substrate is stretched. As a result, damage to the organic light emitting layer OL or the encapsulation layer EL of the pixel P when the substrate 110 is excessively stretched may be reduced or prevented in this embodiment.

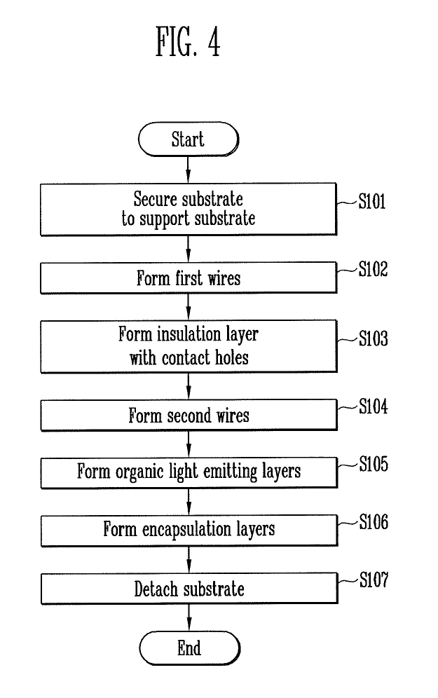

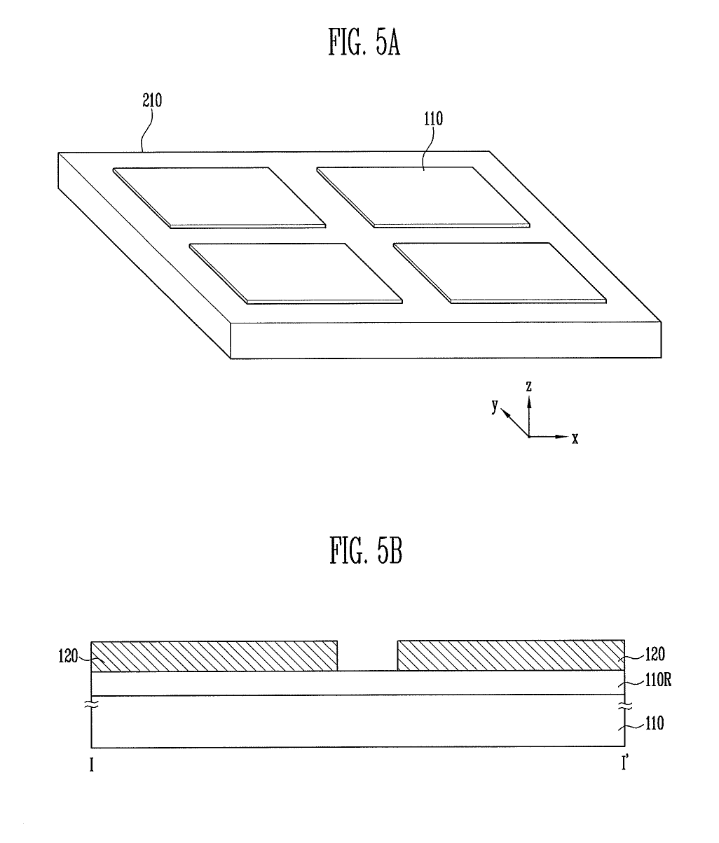

FIG. 4 is a flowchart illustrating a method of fabricating the stretchable display according to this embodiment. FIGS. 5A to 5F are views illustrating stages of a method of fabricating the stretchable display according to this embodiment. Hereinafter, the method of fabricating the stretchable display according to this embodiment will be described in detail with reference to FIG. 4 and FIGS. 5A to 5F. Here, for convenience of description FIG. 5A illustrates a perspective view, and FIGS. 5B to 5F illustrate sectional views taken along line I-I′ of FIG. 3.

As shown in FIG. 5A, the substrate 110 may be secured to a support substrate 210. In order to enhance the efficiency of a process, as shown in FIG. 5A, a plurality of substrates 110 may be simultaneously secured to the support substrate 210. The substrate 110 may be a stretchable substrate. Accordingly, if the substrate 110 were not secured to the support substrate 210, the substrate 110 could become deformed when the substrate 110 is bent or stretched during the process of fabricating the stretchable display. Securing the substrate 110 to the support substrate 210 may prevent the substrate 110 from being deformed. The surface energy of the substrate 110 may be physically and chemically controlled depending on the material of the substrate 110 to be secured to the support substrate 210. (See S101 in FIG. 4.)

As shown in FIG. 5B, the first wires 120 are formed on the substrate 110. In other embodiments, the first wires 120 may be formed on a reflecting plate 100R of the substrate 110. The first wires 120 may be formed in the horizontal direction (x-axis direction). The first wires 120 may be formed of nano wires of the stretchable material, for example, copper (Cu), silver (Ag), gold (Au), graphene, carbon nano tube (CNT), copper phthalocyanine (CuPc), etc., for example. (See S102 in FIG. 4.)

As shown in FIG. 5C, the insulation layer IL may be formed on the first wires 120. The contact hole CNT may be formed through the insulation layer IL to expose the first wires 120. The insulation layer IL may be formed of silicon nitride (SiNx), the double layer of silicon nitride (SiNx)/silicon dioxide (SiO₂) or polyimide, as examples. (See S103 in FIG. 4.)

As shown in FIG. 5D, the second wires 130 are formed on the insulation layer IL. The second wires 130 may be formed in the vertical direction (y-axis direction). As shown, the first wires 120 and the second wires 130 may be formed on different layers to intersect with each other. The second wires 130 may be formed of nano wires of the stretchable material, for example, copper (Cu), silver (Ag), gold (Au), graphene, carbon nano tube (CNT), copper phthalocyanine (CuPc), etc., as examples. (See S104 in FIG. 4.)

As shown in FIG. 5E, the organic light emitting layers OL may be formed on the second wires 130. Each organic light emitting layer OL may be formed to cover n intersections IA of the first wires 120 with the second wires 130. For example, the organic light emitting layer OL may be formed to cover four intersections IA, as shown in FIGS. 2 and 3. The organic light emitting layer OL may be in contact with the first wires 120 via the contact hole CNT, and may be in direct contact with the second wires 120.

The organic light emitting layer OL is the layer that contains an organic light emitting material and emits light when a current flows therein. The organic light emitting layer OL may be formed by dropping the organic light emitting material OM onto a region including the n intersections IA, using an inkjet device ID. The region including the n intersections IA may include the n intersections IA as well as the contact holes CNT formed between the n intersections IA. The inkjet device ID may be aligned above the region including the n intersections IA as shown in FIG. 5E, such that the organic light emitting material OM may be precisely dropped onto the region including the n intersections IA. (See S105 in FIG. 4.)

As shown in FIG. 5F, the encapsulation layers EL may be formed on the organic light emitting layers OL. Each encapsulation layer EL may be formed to cover one organic light emitting layer OL, thus encapsulating the organic light emitting layer OL. The encapsulation layer EL may not be formed throughout the whole surface of the substrate 110. As shown in FIGS. 2 and 3, the encapsulation layer EL may be formed to be wider than the organic light emitting layer OL, thus covering the organic light emitting layer OL. According to this embodiment, each organic light emitting layer OL is individually encapsulated, for every pixel, using the encapsulation layer EL.

The encapsulation layer EL may be formed by dropping an encapsulation material EM onto each organic light emitting layer OL, using an inkjet device ID′. The inkjet device ID′ may be aligned above the organic light emitting layer OL as shown in FIG. 5F, so as to precisely drop the encapsulation material EM and precisely encapsulate the organic light emitting layer OL. (See S106 in FIG. 4.)

The substrate 110 may be detached from the support substrate 210. (See S107 in FIG. 4.)

As described above, according to this embodiment, the organic light emitting material OM is dropped using the inkjet device ID, thus forming the organic light emitting layer OL. Further, in this embodiment, the encapsulation material EM is dropped using the inkjet device ID′, thus forming the encapsulation layer EL. Therefore, according to this embodiment, the organic light emitting layer OL may be individually encapsulated per pixel using the encapsulation layer EL so as to prevent the organic light emitting layer OL or the encapsulation layer EL of the pixel P from being damaged when the substrate 110 is excessively stretched.

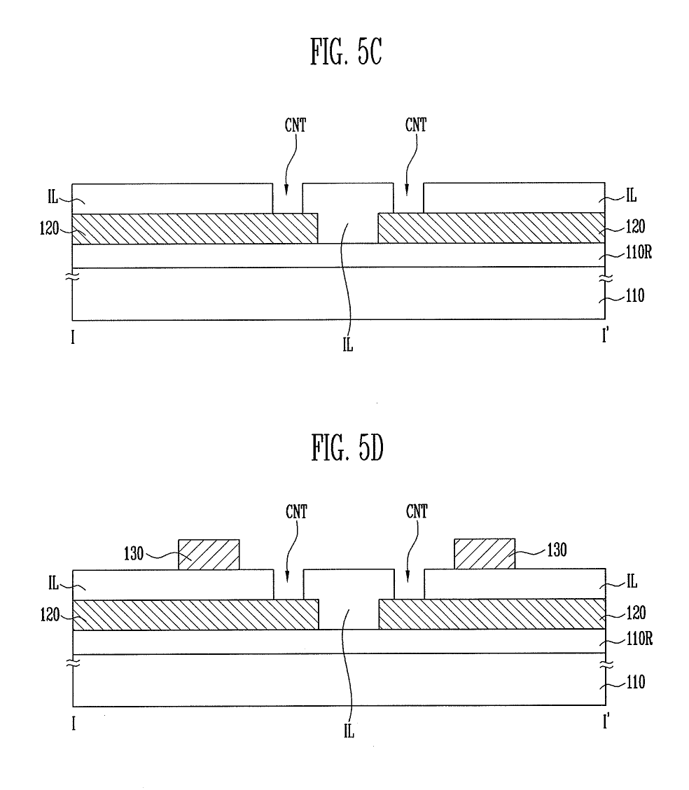

FIG. 6 is a view illustrating a display panel of a stretchable display according to a another embodiment. Referring to FIG. 6, the display panel 10′ of the stretchable display according to this embodiment includes a substrate 110′, first wires 120′, second wires 130′ and pixels P′.

The substrate 110′ may be implemented as a stretchable substrate. In this case, the substrate 110′ may be made of a bendable and stretchable material such as a bendable and stretchable plastics or fabric, as examples.

The substrate 110′ may include a reflecting plate. The reflecting plate may be formed on the substrate 110′. In this case, reflecting plate may be bendable and stretchable. For example, the reflecting plate may be a flexible foil.

First wires 120′ and second wires 130′ may be formed on the substrate 110′ or on the reflecting plate of the substrate 110′. The first wires 120′ and the second wires 130′ may be formed to intersect with each other. For example, the first wires 120′ may be formed to be parallel to each other in a horizontal direction (x-axis direction), and the second wires 120′ may be formed to be parallel to each other in a vertical direction (y-axis direction).

Each of the first and second wires 120′ and 130′ may include an electric conductive wire and an insulator wrapped around the electric conductive wire. The insulator may be implemented as a sheath that covers the electric conductive wire. The electric conductive wire of each of the first and second wires 120′ and 130′ may be formed of a stretchable nano wire.

Pixels P′ may be formed at intersections of the first and second wires 120′ and 130′. For example, the pixels P′ may be formed at all the intersections of the first and second wires 120′ and 130′. As shown in FIG. 6, each of the pixels P′ may include one intersection. The pixels P′ may be implemented as red pixels, green pixels or blue pixels, respectively.

Each pixel P′ may include an organic light emitting layer and an encapsulation layer. The organic light emitting layer is a layer that contains an organic light emitting material to emit light when a current flows. The organic light emitting layer may be implemented as a red organic light emitting layer for emitting red light, a green organic light emitting layer for emitting green light, or a blue organic light emitting layer for emitting blue light. The encapsulation layer is a layer that covers the organic light emitting layer to protect the organic light emitting layer.

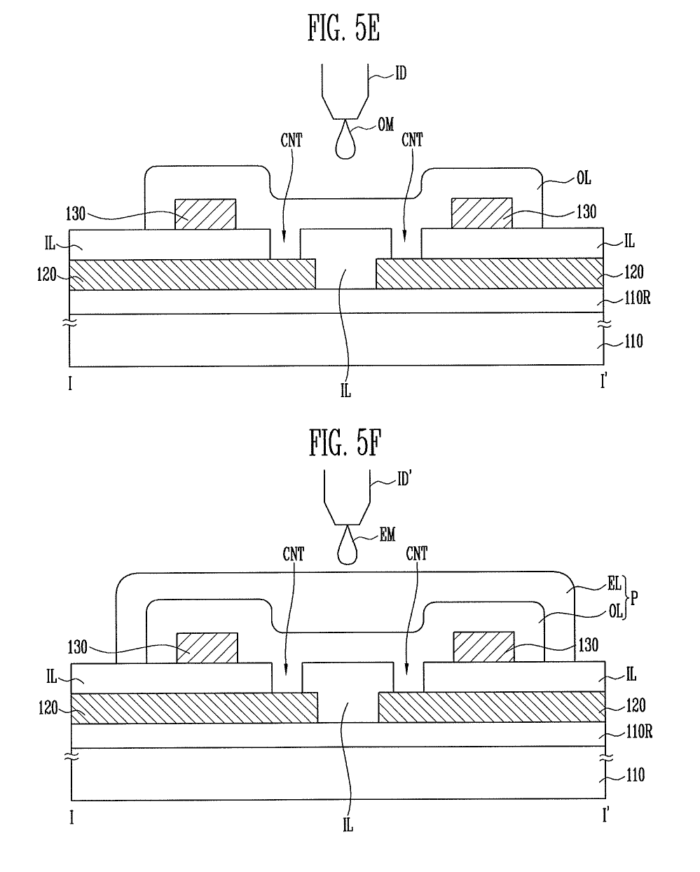

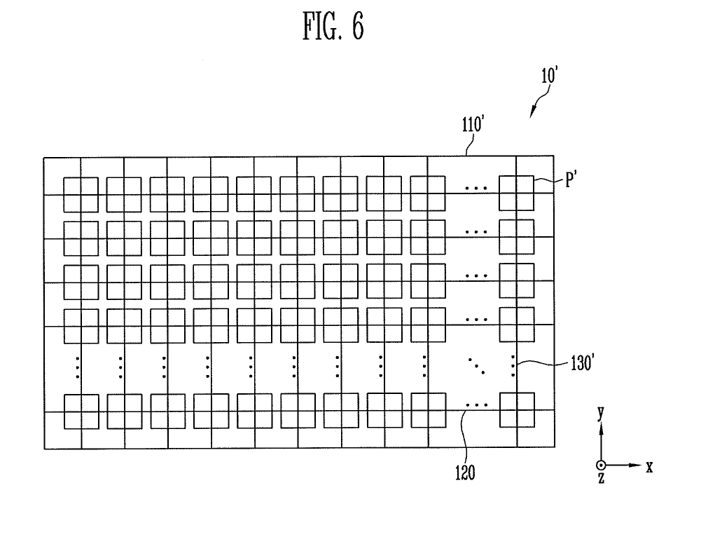

Hereinafter, each pixel P′ will be described in detail with reference to FIGS. 7 and 8.

FIG. 7 illustrates a detailed plan view depicting a portion of the display panel in FIG. 6. FIG. 8 illustrates a sectional view taken along line II-II′ of FIG. 7. As shown in FIGS. 7 and 8, the pixel P′ may include an organic light emitting layer OL′ and an encapsulation layer EL′, and the pixel P′ may be formed to cover one intersection IA′.

Referring to FIGS. 7 and 8, the first wires 120′ may be formed on the substrate 110′ or on the reflecting plate 100R′ of the substrate 110′. The first wires 120′ may be formed in the horizontal direction (x-axis direction). Each of the first wires 120′ may include a first electric conductive wire 121 and a first insulator 122. The first electric conductive wire 121 may be formed of nano wires of a stretchable material, for example, copper (Cu), silver (Ag), gold (Au), graphene, carbon nano tube (CNT), copper phthalocyanine (CuPc), etc. The first insulator 122 may be a sheath that covers the electric conductive wire. Thus, the first electric conductive wire 121 may be insulated by the first insulator 122.

The second wires 130′ may be formed on the first wires 120′. The second wires 130′ may be formed in the vertical direction (y-axis direction). The first wires 120′ and the second wires 130′ may be formed to intersect with each other. Each of the second wires 130′ may include a second electric conductive wire 131 and a second insulator 132. The second electric conductive wire 131 may be formed of nano wires of a stretchable material, for example, copper (Cu), silver (Ag), gold (Au), graphene, carbon nano tube (CNT), copper phthalocyanine (CuPc), etc. The second insulator 132 may be a sheath that covers the electric conductive wire. Thus, the second electric conductive wire 131 may be insulated by the second insulator 132.

By etching the first insulator 122 of the first wire 120′, a first contact hole CNT1 may be formed through the first insulator 122 to expose the first electric conductive wire 121. As shown in FIG. 7, the first contact hole CNT1 may be formed between the intersections IA to expose the first wire 120′. By etching the second insulator 132 of the second wire 130′, a second contact hole CNT2 may be formed through the second insulator 132 to expose the second electric conductive wire 131.

An organic light emitting layer OL′ may be formed on the first and second wires 120′ and 130′. The organic light emitting layer OL′ may be formed to cover the intersection IA′ of the first and second wires 120′ and 130′. For example, the organic light emitting layer OL′ may be formed to cover one intersection IA′. The organic light emitting layer OL′ may be in contact with the electric conductive wire 121 of the first wire 120′ via the first contact hole CNT1, and may be in contact with the electric conductive wire 131 of the second wire 130′ via the second contact hole CNT2.

When a first voltage is supplied to the first electric conductive wire 121 and a second voltage higher than the first voltage is supplied to the second electric conductive wire 131, a current may flow from the second electric conductive wire 131 through the organic light emitting layer OL′ to the first electric conductive wire 121, such that the organic light emitting layer OL′ may emit light. When the second voltage is supplied to the first electric conductive wire 121 and the first voltage is supplied to the second electric conductive wire 131, a current may flow from the first electric conductive wire 121 through the organic light emitting layer OL′ to the second electric conductive wire 131, such that the organic light emitting layer OL′ may emit light.

The encapsulation layer EL′ may be formed on the organic light emitting layer OL′. The encapsulation layer EL′ may be formed to cover the organic light emitting layer OL′, thus encapsulating the organic light emitting layer OL′. The encapsulation layer EL′ may not be formed throughout a whole surface of the substrate 110′. As shown in FIGS. 7 and 8, the encapsulation layer EL′ may be formed to be wider than each organic light emitting layer OL′, thus covering each organic light emitting layer OL′. That is, according to this embodiment, the organic light emitting layer OL′ is individually encapsulated, for every pixel, using the encapsulation layer EL′.

According to comparative embodiments, the encapsulation layer EL′ may be formed over the whole surface of the substrate 110′. In this case, if the substrate 110′ is excessively stretched, the organic light emitting layer OL′ or the encapsulation layer EL′ of the pixel P′ could be damaged because the organic light emitting layer OL′ or the encapsulation layer EL′ of the pixel P′ would also be stretched. However, when the organic light emitting layer OL′ is individually encapsulated, for every pixel, using the encapsulation layer EL′ according to this embodiment, even though the substrate 110 is excessively stretched, the organic light emitting layer OL′ or the encapsulation layer EL′ of the pixel P may not be damaged because the organic light emitting layer OL′ or the encapsulation layer EL′ of the pixel P′ is not stretched when the substrate is stretched. As a result, damage to the organic light emitting layer OL′ or the encapsulation layer EL′ of the pixel P′ when the substrate 110′ is excessively stretched may be reduced or prevented according to this embodiment.

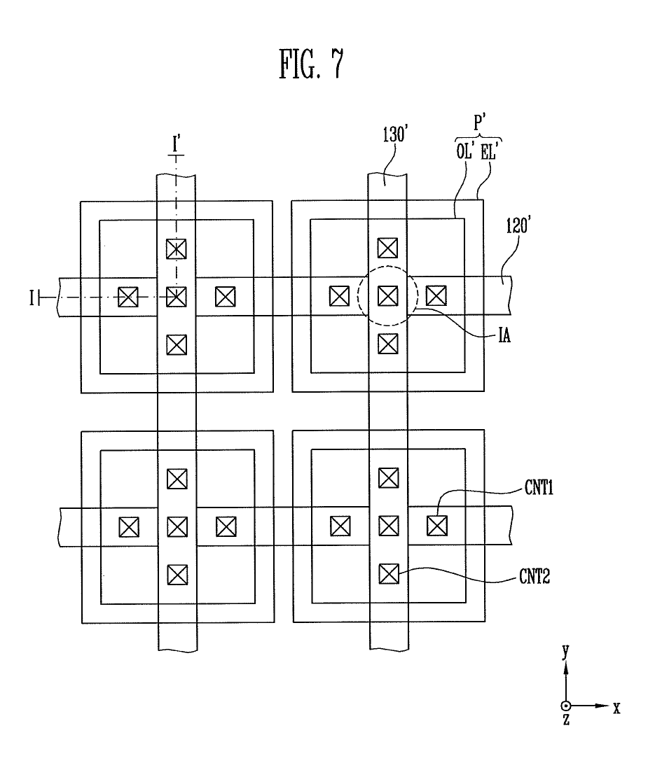

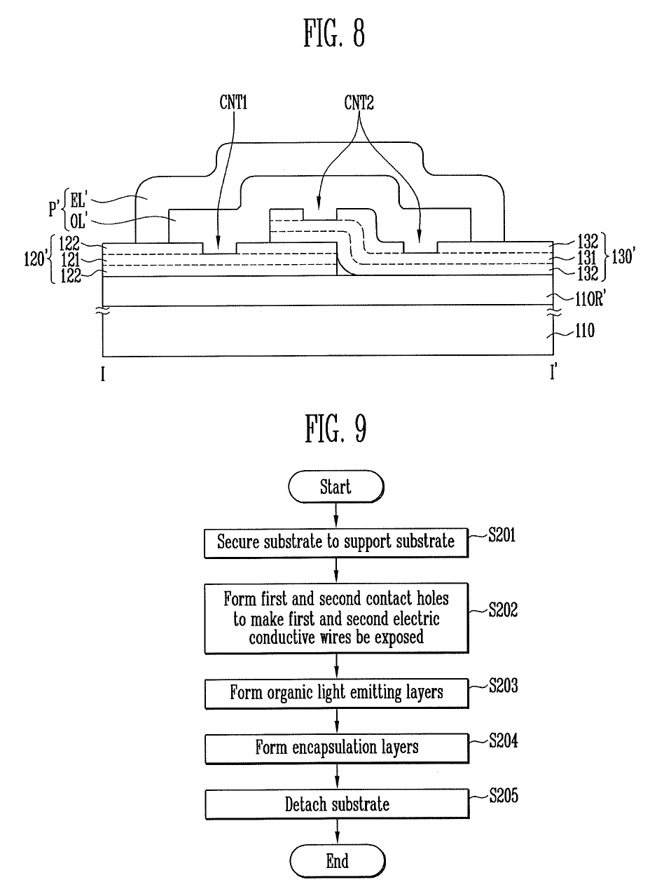

FIG. 9 is a flowchart illustrating a method of fabricating the stretchable display according to this embodiment. FIGS. 10A to 10D illustrate stages of a method of fabricating the stretchable display according to this embodiment, in perspective and sectional views. Hereinafter, the method of fabricating the stretchable display according to this embodiment will be described in detail with reference to FIG. 9 and FIGS. 10A to 10D. FIG. 10A illustrates a perspective view, and FIGS. 10B to 10D illustrate sectional views taken along line I-I′ of FIG. 8, for convenience of description.

As shown in FIG. 10A, the substrate 110′ is secured to a support substrate 210′. In order to enhance the efficiency of a process, a plurality of substrates 110′ may be simultaneously secured to the support substrate 210′, as shown in FIG. 10A. The substrate 110′ may be a stretchable substrate. Accordingly, if the substrate is not secured to the support substrate 210′, the substrate 110′ could become deformed when the substrate 110′ is bent or stretched during the process. The securing operation may prevent the substrate 110′ from being deformed. The surface energy of the substrate 110′ may be physically and chemically controlled depending on the material of the substrate 110′ to be secured to the support substrate 210′. (See S201 in FIG. 9.)

As shown in FIG. 10B, the first and second wires 120′ and 130′ may be formed on the substrate 110′. By etching the insulator 122 of the first wire 120′, the first contact hole CNT1 may be formed to expose the first electric conductive wire 121 of the first wire 120′. By etching the second insulator 132 of the second wire 130′, the second contact hole CNT2 may be formed to expose the second electric conductive wire 131 of the second wire 130′. (See S202 in FIG. 9.)

As shown in FIG. 10C, the organic light emitting layers OL′ may be formed on the first and second wires 120′ and 130′. Each organic light emitting layer OL′ may be formed to cover one intersection IA′ of the first and second wires 120′ and 130′. The organic light emitting layer OL′ may be in contact with the electric conductive wire 121 of the first wire 120′ via the first contact hole CNT1, and may be in contact with the electric conductive wire 131 of the second wire 130′ via the second contact hole CNT2.

The organic light emitting layer OL′ is the layer that contains an organic light emitting material and emits light when a current flows therein. The organic light emitting layer OL′ may be formed by dropping the organic light emitting material OM′ onto a region including one intersection IA′, using an inkjet device ID′. The region including one intersection IA′ may include the intersection IA′ as well as the first and second contact holes CNT1 and CNT2 formed between intersections adjacent to the intersection IA′. The inkjet device ID′ may be aligned above the region including one intersection IA′ as shown in FIG. 10C, such that the organic light emitting material OM′ may be precisely dropped onto the region including one intersection IA′. (See S203 in FIG. 9.)

As shown in FIG. 10D, the encapsulation layers EL′ may be formed on the organic light emitting layers OL′. Each encapsulation layer EL′ may be formed to cover one organic light emitting layer OL′, thus encapsulating the organic light emitting layer OL′. The encapsulation layer EL′ may not be formed throughout the whole surface of the substrate 110′. As shown in FIGS. 7 and 8, the encapsulation layer EL′ may be formed to be wider than the organic light emitting layer OL′, thus covering the organic light emitting layer OL′. According to this embodiment, each organic light emitting layer OL′ is individually encapsulated, for every pixel P′, using the encapsulation layer EL′.

The encapsulation layer EL′ may be formed by dropping the encapsulation material EM′ onto each organic light emitting layer OL′, using the inkjet device ID′. The inkjet device ID′ may be aligned above the organic light emitting layer OL′ as shown in FIG. 10D, so as to precisely drop the encapsulation material EM′ and precisely encapsulate the organic light emitting layer OL′. (See S204 in FIG. 9.)

The substrate 110′ may be detached from the support substrate 210′. (See S205 in FIG. 9.)

As described above, according to this embodiment, the organic light emitting material OM′ may be dropped using the inkjet device ID′, thus forming the organic light emitting layer OL′. Further, the encapsulation material EM′ may be dropped using the inkjet device ID′, thus forming the encapsulation layer EL′. The organic light emitting layer OL′ may be individually encapsulated per pixel using the encapsulation layer EL′ so as to prevent the organic light emitting layer OL′ or the encapsulation layer EL′ of the pixel P′ from being damaged.

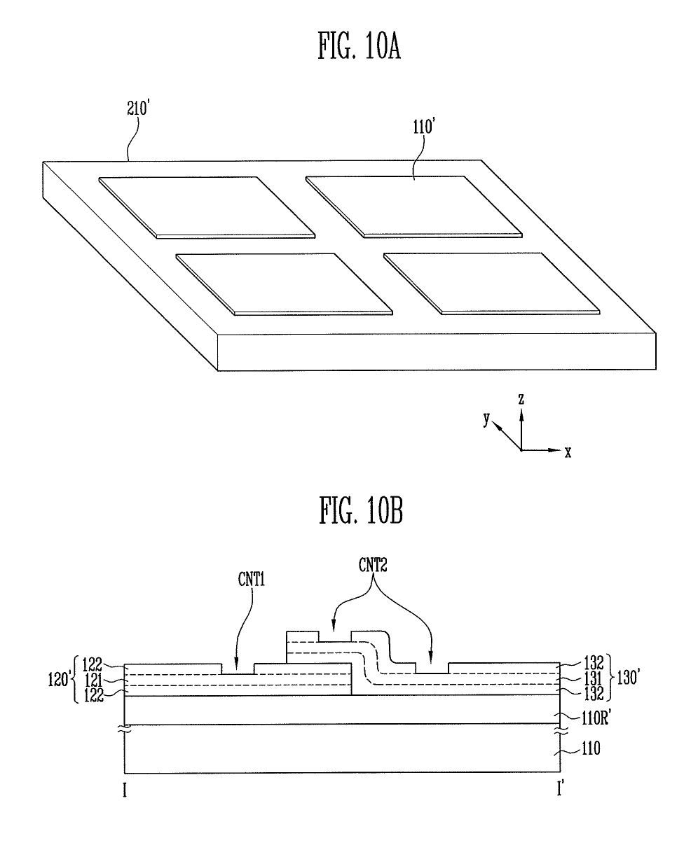

FIG. 11 is a block diagram illustrating a stretchable display according to an embodiment. Referring to FIG. 11, the stretchable display according to this embodiment includes a display panel 10, and a first driver 300 and a second driver 400, which are configured to drive the display panel 10. In FIG. 11, the display panel 10 is shown as being formed in a rectangular shape.

The display panel 10 may be the stretchable display according to the embodiment illustrated in FIG. 1, where the pixels P of the display panel 10 include n intersections. In other implementations, the display panel may be the display panel illustrated in FIG. 6. The display panel 10 has already been described in detail with reference to FIGS. 1 and 6.

As shown in FIG. 11, the first driver 300 may be formed on either the left or the right side of the display panel 10. The second driver 400 may be formed on either the upper or the lower side of the display panel 10. The first driver 300 may be connected to the first wires 120 of the display panel 10 to supply a first drive voltage to the first wires 120. The first driver 300 may sequentially supply the first drive voltage to the first wires 120. In other implementations, the first driver 300 may simultaneously supply the first drive voltage to all of the first wires 120. The first drive voltage may be a low-potential voltage. The second driver 400 may be connected to the second wires 130 of the display panel 10 to supply second drive voltages to the second wires 130. The second drive voltages may have a level that is higher than the low-potential voltage.

The organic light emitting layers OL of the pixels P of the display panel 10 may emit light according to a difference between the first drive voltage and the second drive voltage. For example, the organic light emitting layers OL of the pixels P of the display panel 10 may emit light with higher luminance as the difference between the first and second drive voltages increases. When the first driver 300 sequentially supplies the first drive voltage to the first wires 120, the pixels P of the display panel 10 may emit light according to the sequentially supplied voltage of the first wires 120. When the first driver 300 simultaneously supplies the first drive voltage to the first wires 120, the pixels P of the display panel 10 may emit light simultaneously.

The stretchable display according to the embodiment may further include a timing controller to control the timing of the first and second drivers 300 and 400.

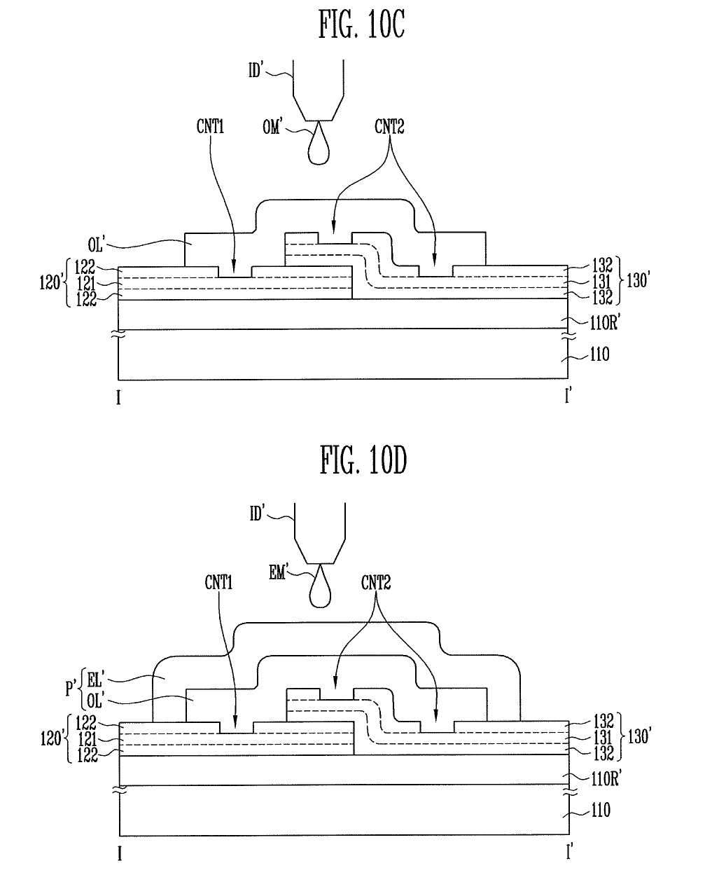

FIG. 12 is a block diagram illustrating a stretchable display according to another embodiment. Referring to FIG. 12, the stretchable display according to this embodiment may include a display panel 10 and an integrated driver 500 that drives the display panel 10. In FIG. 12, the display panel 10 may be formed in a rectangular shape.

As an example, the display panel 10 may be the stretchable display illustrated in FIG. 1, where the pixels P of the display panel 10 include n intersections. In other implementations, the stretchable display illustrated in FIG. 6 may be used. The display panel 10 has already been described in detail with reference to FIGS. 1 and 6.

As shown in FIG. 12, the integrated driver 500 may be formed on a side of the display panel 10. The integrated driver 500 may be connected to the first wires 120 of the display panel 10 to simultaneously supply a first drive voltage to the first wires 120. The first drive voltage may be a low-potential voltage. The integrated driver 500 may be connected to the second wires 130 of the display panel 10 to supply second drive voltages to the second wires 130. The second drive voltages may have a level that is higher than the low-potential voltage.

The organic light emitting layer OL of the pixels P of the display panel 10 emits light according to a difference between the first drive voltage and the second drive voltage. The organic light emitting layers OL of the pixels P of the display panel 10 may emit light with a higher luminance as the difference between the first and second drive voltages increases. As the first driver 300 simultaneously supplies the first drive voltage to the first wires 120, the pixels P of the display panel 10 may emit light simultaneously.

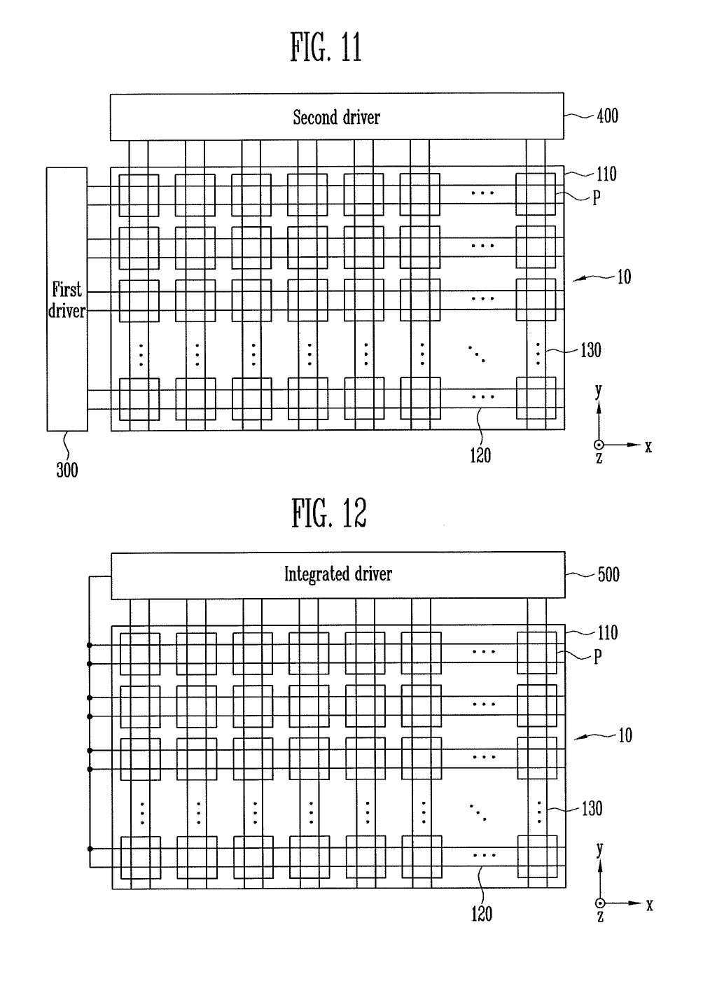

FIG. 13 is a block diagram illustrating a stretchable display according to a another embodiment. Referring to FIG. 13, the stretchable display according to the further embodiment may include a display panel 10″, and a first driver 300′ and a second driver 400′ configured to drive the display panel. As illustrated in FIG. 13, the display panel 10″ may be formed in a fan shape.

When the display panel 10″ is formed in the fan shape, first wires 120″ may be formed to be parallel to the arc of the fan shape. Second wires 130″ may extend from the center of the fan shape to the arc thereof in such a way as to intersect with the first wires 120″. The display panel of this embodiment may be similar to the display panel illustrated in in FIG. 6, except that the display panel 10″ is formed in the fan shape. The pixels P″ of the display panel 10″ may be formed at every intersection of the first wires 120″ and the second wires 130″. In other implementations, the display panel may be similar to the display panel illustrated in FIG. 1, except for being in the fan shape. The display panel has already been described in detail with reference to FIGS. 1 and 6.

As shown in FIG. 13, the first driver 300′ may be formed on either the left side or the right side of the display panel 10″, while the second driver 400′ may be formed at the center of the fan shape. The first driver 300′ may be connected to the first wires 120″ of the display panel 10″ to supply a first drive voltage to the first wires 120″. The first driver 300′ may sequentially supply the first drive voltage to the first wires 120″. In other implementations, the first driver 300′ may simultaneously supply the first drive voltage to the first wires 120″. The first drive voltage may be a low-potential voltage. The second driver 400′ may be connected to the second wires 130″ of the display panel 10″ to supply second drive voltages to the second wires 130″. The second drive voltages may have a level that is higher than the low-potential voltage.

The organic light emitting layer OL of the pixels P″ of the display panel 10″ emits light according to a difference between the first drive voltage and the second drive voltage. For example, the organic light emitting layer OL of the pixels P″ of the display panel 10″ emits light with higher luminance as the difference between the first and second drive voltages increases. When the first driver 300′ sequentially supplies the first drive voltage to the first wires 120″, the pixels P″ of the display panel 10″ may emit light according to each of the first wires 120″. When the first driver 300′ simultaneously supplies the first drive voltage to the first wires 120″, the pixels P″ of the display panel 10″ may emit light simultaneously.

The stretchable display according to the embodiment may further include a timing controller to control the timing of the first and second drivers 300′ and 400′.

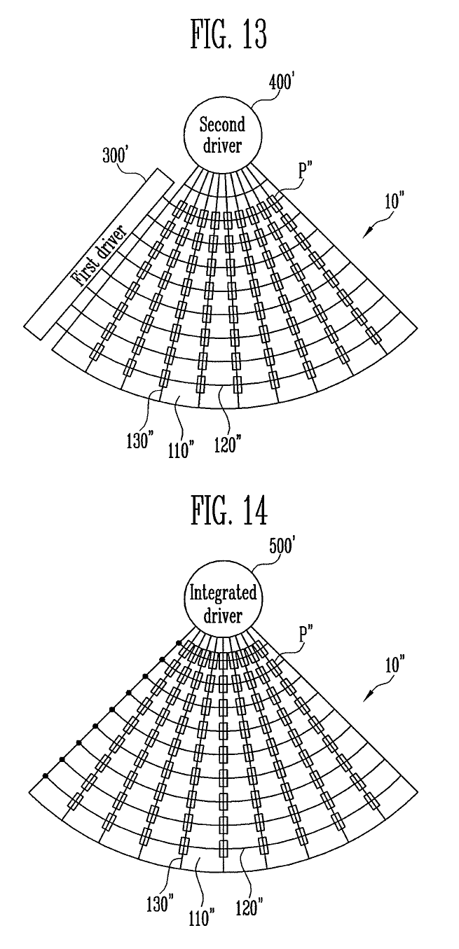

FIG. 14 is a block diagram illustrating a stretchable display according to another embodiment. Referring to FIG. 14, the stretchable display according to this embodiment may include a display panel 10″ and an integrated driver 500′ that drives the display panel 10″. In FIG. 14, the display panel 10″ may be formed in a fan shape.

When the display panel 10″ is formed in the fan shape, first wires 120″ may be formed to be parallel to the arc of the fan shape, and the second wires 130″ may extend from the center of the fan shape to the arc thereof in such a way as to intersect with the first wires 120″. The display panel of this embodiment may be similar to the display panel illustrated in FIG. 6, except that the display panel 10″ is formed in the fan shape. The pixels P″ of the display panel 10″ may be formed on every intersection. In other implementations, the display panel may be similar to the display panel in FIG. 1, except for being in the fan shape. The display panel has already been described in detail with reference to FIGS. 1 and 6.

As shown in FIG. 14, the integrated driver 500′ may be formed at the center of the fan shape. The integrated driver 500′ may be connected to the first wires 120″ of the display panel 10″ to simultaneously supply the first drive voltage to the first wires 120″. The first drive voltage may be a low-potential voltage. Further, the integrated driver 500′ may be connected to the second wires 130″ of the display panel 10″ to supply the second drive voltages to the second wires 130″. The second drive voltages may have a level that is higher than the low-potential voltage.

The organic light emitting layer OL of the pixels P″ of the display panel 10″ emits light according to a difference between the first drive voltage and the second drive voltage. For example, the organic light emitting layer OL of the pixels P″ of the display panel 10″ emits light with higher luminance as the difference between the first and second drive voltages increases. When the integrated driver 500′ simultaneously supplies the first drive voltage to the first wires 120″, the pixels P″ of the display panel 10″ may emit light simultaneously.

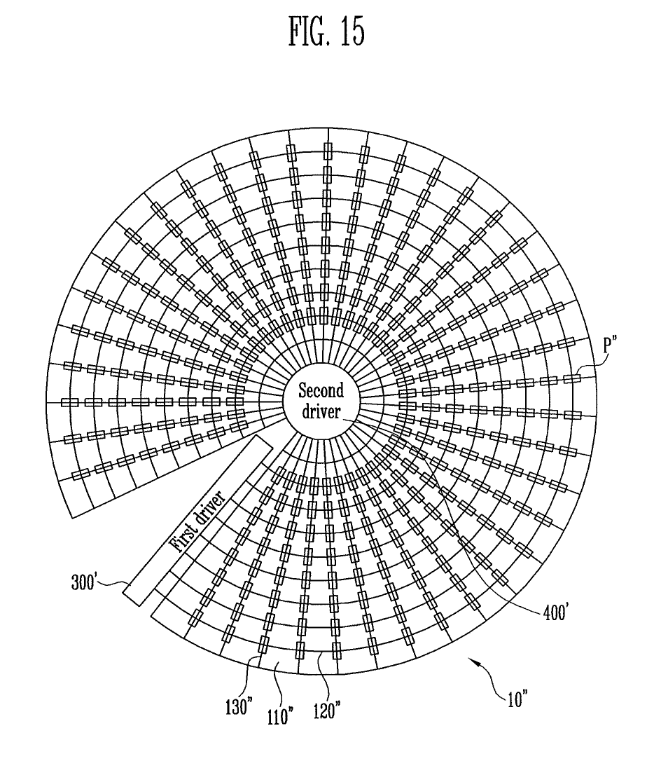

FIG. 15 is a block diagram illustrating a stretchable display according to another embodiment. Referring to FIG. 15, the stretchable display according to this embodiment includes a display panel 10″, and a first driver 300′ and a second driver 400′ that drive the display panel 10″. In FIG. 15, the display panel 10″ may be formed in a circular shape.

When the display panel 10″ is formed in the circular shape, first wires 120″ may be formed to be parallel to the circumference of the circle. Second wires 130″ may extend from the center of the circle to the circumference thereof in such a way as to intersect with the first wires 120″. The display panel of this embodiment may similar to the display panel illustrated in FIG. 6, except that the display panel 10″ is formed in the circular shape. That is, the pixels P″ of the display panel 10″ may be formed on every intersection. In other implementations, the display panel may be similar to the display panel illustrated in FIG. 1, except for being formed in the circular shape. The display panel 10″ has already been described in detail with reference to FIGS. 1 and 6.

As shown in FIG. 15, the display panel 10 may be formed in the circular shape. The first driver 300′ may be formed to extend from the center of the circle to the circumference thereof, and the second driver 400′ may be formed at the center of the circle. The first driver 300′ may be connected to the first wires 120″ of the display panel 10″ to supply the first drive voltage to the first wires 120″. The first driver 300′ may sequentially supply the first drive voltage to the first wires 120″. In other implementations, the first driver 300′ may simultaneously supply the first drive voltage to the first wires 120″. The first drive voltage may be a low-potential voltage.

The second driver 400′ may be connected to the second wires 130″ of the display panel 10″ to supply second drive voltages to the second wires 130″. The second drive voltages may have a level that is higher than the low-potential voltage.

The organic light emitting layer OL of the pixels P″ of the display panel 10″ emits light according to a difference between the first drive voltage and the second drive voltage. For example, the organic light emitting layer OL of the pixels P″ of the display panel 10″ may emit light with higher luminance as the difference between the first and second drive voltages increases. When the first driver 300′ sequentially supplies the first drive voltage to the first wires 120″, the pixels P″ of the display panel 10″ may emit light according to each first wire 120″. When the first driver 300′ simultaneously supplies the first drive voltage to the first wires 120″, the pixels P″ of the display panel 10″ may simultaneously emit light.

The stretchable display according to the embodiment may further include a timing controller to control the timing of the first and second drivers 300′ and 400′.

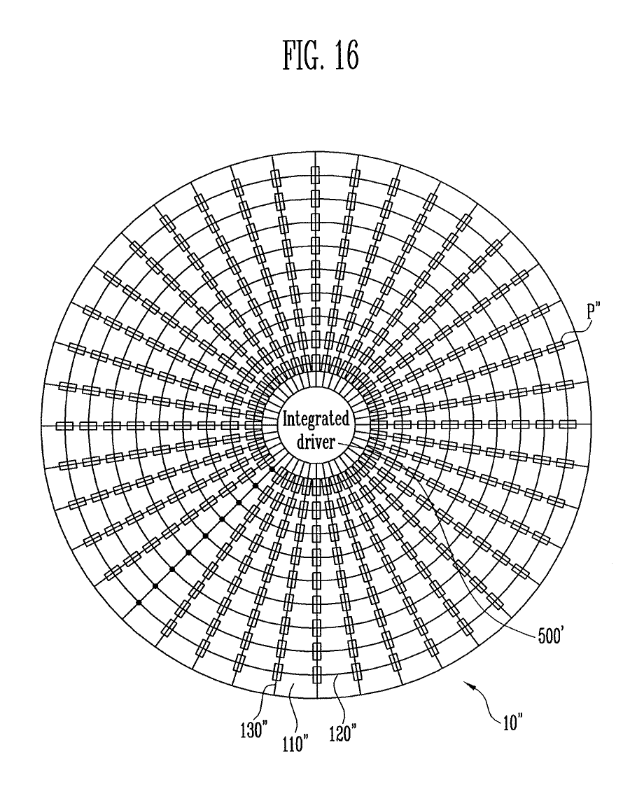

FIG. 16 is a block diagram illustrating a stretchable display according to another embodiment. Referring to FIG. 16, the stretchable display according to this embodiment includes a display panel 10″ and an integrated driver 500′ configured to drive the display panel 10″. In FIG. 16, the display panel 10″ is formed in a circular shape.

When the display panel 10″ is formed in the circular shape, first wires 120″ may be formed to be parallel to the circumference of the circle. Second wires 130″ may extend from the center of the circle to the circumference thereof in such a way as to intersect with the first wires 120″. The display panel of this embodiment may be similar to the display panel of the stretchable display illustrated in FIG. 6 except that the display panel 10″ is formed in the circular shape. The pixels P″ of the display panel 10″ may be formed on every intersection. In other implementations, the display panel may be similar to the display panel illustrated in FIG. 1, except for being in the circular shape. The display panel 10″ has already been described in detail with reference to FIGS. 1 and 6.

As shown in FIG. 16, the integrated driver 500′ may be formed at the center of the circle. The integrated driver 500′ may be connected to the first wires 120″ of the display panel 10″ to simultaneously supply the first drive voltage to the first wires 120″. The first drive voltage may be a low-potential voltage. The integrated driver 500′ may be connected to the second wires 130″ of the display panel 10″ to supply the second drive voltages to the second wires 130″. The second drive voltages may have a level that is higher than the low-potential voltage.

The organic light emitting layer OL of the pixels P″ of the display panel 10″ emits light according to a difference between the first drive voltage and the second drive voltage. For example, the organic light emitting layer OL of the pixels P″ of the display panel 10″ may emit light with higher luminance as the difference between the first and second drive voltages increases. When the first driver simultaneously supplies the first drive voltage to the first wires 120″, the pixels P″ of the display panel 10″ may simultaneously emit light.

As shown in FIGS. 11 to 16, the embodiment allows the display panel to have various shapes, such as a rectangular shape, a fan shape or a circular shape, thus enabling the stretchable display to be variously designed and thereby achieving an high aesthetic effect.

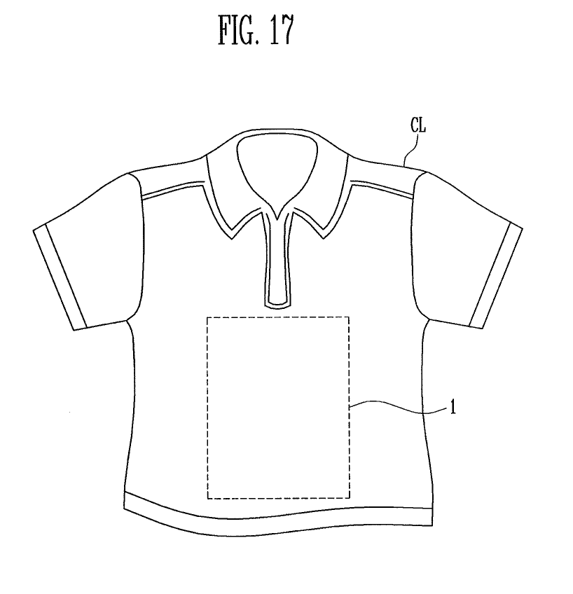

FIG. 17 illustrates an application example for the stretchable display according to embodiments. Referring to FIG. 17, the stretchable display 1 is bendable and stretchable. Accordingly, the stretchable display may be formed on a specific portion of articles of clothing CL. The substrate of the stretchable display 1 may be formed of fabric that is similar to the fabric of the clothing CL. When the stretchable display 1 is formed on a specific portion of clothing CL as shown in FIG. 17, it may be possible to display a predetermined color, image, motif, pattern, etc. on the specific portion of the clothing CL, thus enabling the design of the clothing CL to be further diversified.

Although FIG. 17 illustrates the stretchable display 1 as being a rectangular shape, in other implementations, the stretchable display 1 may be formed in the fan shape or the circular shape as shown in FIGS. 13 to 16. FIG. 17 shows only one example of a method of applying the stretchable display according to the embodiment, it should be understood that many variations are possible.

By summation and review, if the stretchable display is to be made as the organic light emitting display device, it is desirable that a substrate on which pixels including organic light emitting diodes are formed be easily stretchable. However, it is difficult to provide such stretchable display. For example, when a stretchable display is stretched, the pixels may also be stretched. This may undesirably cause damage to the pixels.

According to embodiments, an organic light emitting layer may be formed by dropping an organic light emitting material using an inkjet device An encapsulation layer may also be formed by using the inkjet device to drop the encapsulation material. Thus, the organic light emitting layer may be individually encapsulated per pixel by using the encapsulation layer. Embodiments address the issue of damage that may occur to the organic light emitting layer or the encapsulation layer of the pixel is damaged when the substrate is excessively stretched. In particular, embodiments provide a stretchable display and a method of fabricating the stretchable display, in which damage to pixels when the stretchable display is stretched may be reduced or prevented.

Further, embodiment allow the display panel to have various shapes, such as a rectangular shape, a fan shape or a circular shape, thus enabling the stretchable display to be variously designed and thereby achieving high aesthetic effect.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A stretchable display, comprising:
a substrate;
first wires on the substrate;
second wires on the first wires, the second wires intersecting the first wires;
organic light emitting layers at intersections of the first and second wires; and
encapsulation layers on the respective organic light emitting layers, the encapsulation layers individually covering the respective organic light emitting layers.

2. The stretchable display as claimed in claim 1, further comprising:
an insulation layer between the first wires and the second wires, the insulation layer electrically insulating the first wires from the second wires.

3. The stretchable display as claimed in claim 2, wherein the organic light emitting layers directly contact the second wires, and contact the first wires via a contact hole, the contact hole extending through the insulation layer to expose the first wires.

4. The stretchable display as claimed in claim 1, wherein each of the first wires includes:
a first electric conductive wire; and
a first insulator wrapped around the first electric conductive wire.

5. The stretchable display as claimed in claim 4, wherein the organic light emitting layers contact the first electric conductive wire via a first contact hole, the first contact hole extending through the first insulator to expose the first electric conductive wire.

6. The stretchable display as claimed in claim 4, wherein each of the second wires includes:
a second electric conductive wire; and
a second insulator wrapped around the second electric conductive wire.

7. The stretchable display as claimed in claim 6, wherein the organic light emitting layers contact the second electric conductive wire via a second contact hole, the second contact hole extending through the second insulator to expose the second electric conductive wire.

8. The stretchable display as claimed in claim 1, further comprising:
a first driver that supplies a first drive voltage to the first wires; and
a second driver that supplies second drive voltages to the second wires.

9. The stretchable display as claimed in claim 8, further comprising:
an integrated driver that simultaneously supplies the first drive voltage to the first wires and supplies the second drive voltages to the second wires.

10. The stretchable display as claimed in claim 1, wherein the substrate has a rectangular shape, a circular shape, or a fan shape.

11. The stretchable display as claimed in claim 1, wherein the substrate includes a reflecting plate.

12. A method of fabricating a stretchable display, the method comprising:
securing a stretchable substrate to a support substrate;
forming first wires on the stretchable substrate;
forming second wires to intersect with the first wires;
forming organic light emitting layers by dropping an organic light emitting material onto intersections of the first and second wires; and
forming encapsulation layers by dropping an encapsulation material onto the respective organic light emitting layers to individually cover the respective organic light emitting layers.

13. The method as claimed in claim 12, further comprising:
forming an insulation layer between the first wires and the second wires to electrically insulate the first wires from the second wires.

14. The method as claimed in claim 13, further comprising:
forming at least one contact hole through the insulation layer to expose the first wires.

15. The method as claimed in claim 14, wherein forming the organic light emitting layers by dropping the organic light emitting material onto the intersections of the first and second wires includes dropping the organic light emitting material to cover the intersections of the first and second wires and the contact hole.

16. The method as claimed in claim 12, further comprising:
forming a first contact hole through an insulation material of the first wires to expose an electric conductive material of the first wires; and
forming a second contact hole through an insulation material of the second wires to expose an electric conductive material of the second wires.

17. The method as claimed in claim 16, wherein forming the organic light emitting layers by dropping the organic light emitting material onto the intersections of the first and second wires includes dropping the organic light emitting material to cover the intersections of the first and second wires and the first and second contact holes using an inkjet device.

18. The method as claimed in claim 12, wherein forming the encapsulation layers by dropping the encapsulation material to the respective organic light emitting layers to cover the respective organic light emitting layers includes dropping the encapsulation material onto the respective organic light emitting layers using an inkjet device.

19. A method of fabricating a stretchable display, the method comprising:
securing a stretchable substrate to a support substrate;
foaming first contact holes by etching first insulators of first wires formed on the stretchable substrate, the first contact holes exposing first electric conductive wires of the first wires;
forming second contact holes by etching second insulators of second wires formed on the stretchable substrate, the second contact holes exposing second electric conductive wires of the second wires;
forming organic light emitting layers by dropping an organic light emitting material to cover intersections of the first and second wires and the first and second contact holes; and
forming encapsulation layers by dropping an encapsulation material onto the respective organic light emitting layers to individually cover the respective organic light emitting layers.

20. The method as claimed in claim 19, wherein forming the organic light emitting layers by dropping the organic light emitting material to cover the intersections of the first and second wires and the first and second contact holes is carried out using an inkjet device, and
forming the encapsulation layers by dropping the encapsulation material onto the respective organic light emitting layers to cover the respective organic light emitting layers is carried out using the inkjet device.
